(19) United States
(12) Patent Application Publication
(10) Pub. No.: US 2024/0274774 A1
(43) Pub. Date: Aug. 15, 2024

(54) LIGHT EMITTING DIODE STRUCTURE AND LIGHT EMITTING DEVICE

(71) Applicant: Xiamen San'an Optoelectronics Co., Ltd., Fujian (CN)

(72) Inventors: Jenlung YANG, Fujian (CN); Feng ZUO, Fujian (CN); Liming ZHANG, Fujian (CN); Weipeng LIN, Fujian (CN); Chung-Ying CHANG, Fujian (CN)

(73) Assignee: Xiamen San'an Optoelectronics Co., Ltd., Fujian (CN)

(21) Appl. No.: 18/644,133

(22) Filed: Apr. 24, 2024

Related U.S. Application Data
(63) Continuation of application No. PCT/CN2021/127442, filed on Oct. 29, 2021.

(51) Int. Cl. H01L 33/62; H01L 27/02; H01L 27/15; H01L 33/38

(52) U.S. Cl. CPC H01L 33/62; H01L 27/0248; H01L 27/15; H01L 33/38

(57) ABSTRACT

A light emitting device and a light emitting diode structure are provided. The light emitting diode structure includes a light emitting diode, a protection diode, an insulating layer, two pads, and a conductive structure. The protection diode is connected in antiparallel to the light emitting diode. Each diode includes an epitaxial structure and electrodes located on the epitaxial structure. The insulating layer covers the epitaxial structure of each diode. A first pad is located on the insulating layer and electrically connected to a first electrode and a fourth electrode. A second pad is located on the insulating layer and electrically connected to a second electrode. The conductive structure is connected to the second pad and electrically connected to the N-type semiconductor layer of the protection diode. A material of the conductive structure and a material of the first electrode are different.

### CROSS-REFERENCE TO RELATED APPLICATION

This application is a continuation of international application of PCT application serial no. PCT/CN2021/127442 filed on Oct. 29, 2021. The entirety of the above mentioned patent application is hereby incorporated by reference herein and made a part of this specification.

### BACKGROUND

### Technical Field

The disclosure relates to the field of semiconductor technology, and in particular, to a highly reliable light emitting diode structure and a light emitting device.

### Description of Related Art

A light emitting diode (LED) is a semiconductor device that uses energy released when carriers recombine to emit light. LED chips have many advantages such as low power consumption, pure color, long service life, small size, fast response time, energy saving and environmental protection and thus are widely used in lighting, visible light communications, luminous displays, and other scenarios. LED chips are categorized into three structures: the lateral structure, the flip-chip structure, and the vertical structure. Compared to the conventional lateral structure, the flip-chip LED chip structure is to invert the diode structure and emit light from the sapphire side, while the electrode side can be fixed on a substrate with improved heat dissipation.

In order to prevent a LED chip from being damaged due to electro-static discharge (ESD), at present, a common solution is to use an additional Zener diode to be connected in antiparallel to the LED chip, so as to prevent the LED chip from being damaged by reverse bias or ESD current. When an ESD phenomenon occurs, the high-voltage characteristics of static electricity cause the Zener diode to operate in its breakdown voltage region. At this time, the Zener diode connected in antiparallel to the LED chip can effectively prevent the LED chip from being damaged by static electricity.

However, there are several problems with this solution. 1. It is difficult to install the Zener diode during the packaging process. 2. The costs of this packaging process is relatively high. 3. Before the packaging is completed, the LED chip is very likely to fail due to static electricity and other factors. 4. Since the Zener diode is placed close to the LED chip in the package, the luminous efficiency of the LED package will be reduced due to the light absorbed by the Zener diode, so the yield of the LED package is decreased.

Further, LED chips in UV (ultraviolet) products are limited by their epitaxial capabilities, and their negative anti-ESD capability is far weaker than their positive anti-ESD capability. A suitable solution has not yet been found.

Therefore, how to improve the anti-ESD capability of the LED chips and further improve the negative anti-ESD capability of the LED chips has been a long-standing technical problem that needs to be solved by a person having ordinary skill in the art.

### SUMMARY

The disclosure provides a light emitting diode structure including a light emitting diode, a protection diode, an insulating layer, a first pad, a second pad, and a conductive structure.

The light emitting diode includes a first epitaxial structure, a first electrode, and a second electrode. The first epitaxial structure includes a first semiconductor layer, a first light emitting layer, and a second semiconductor layer stacked in sequence. The first electrode is located on the first epitaxial structure and electrically connected to the first semiconductor layer, and the second electrode is located on the first epitaxial structure and electrically connected to the second semiconductor layer. The protection diode is connected in antiparallel to the light emitting diode and includes a second epitaxial structure and a fourth electrode. The second epitaxial structure includes a third semiconductor layer, a second light emitting layer, and a fourth semiconductor layer stacked in sequence. The first epitaxial structure and the second epitaxial structure are separated from each other. The fourth electrode is located on the second epitaxial structure and electrically connected to the fourth semiconductor layer. The insulating layer covers the first epitaxial structure and the second epitaxial structure and has a first opening, a second opening, a third opening, and a fourth opening. The first pad is located on the insulating layer and electrically connected to the first electrode and the fourth electrode respectively through the first opening and the fourth opening. The second pad is located on the insulating layer and electrically connected to the second electrode through the second opening. The conductive structure is connected to the second pad and electrically connected to the third semiconductor layer through the third opening. A material of the conductive structure and a material of the first electrode are different.

The disclosure further provides a light emitting diode structure including a light emitting diode, a protection diode, an insulating layer, a first pad, a second pad, and a conductive structure.

The light emitting diode includes a first epitaxial structure, a first electrode, and a second electrode. The first epitaxial structure includes a first semiconductor layer, a first light emitting layer, and a second semiconductor layer stacked in sequence. The first electrode is located on the first epitaxial structure and electrically connected to the first semiconductor layer, and the second electrode is located on the first epitaxial structure and electrically connected to the second semiconductor layer. The protection diode is connected in antiparallel to the light emitting diode and includes a second epitaxial structure and a fourth electrode. The second epitaxial structure includes a third semiconductor layer, a second light emitting layer, and a fourth semiconductor layer stacked in sequence. The first epitaxial structure and the second epitaxial structure are separated from each other. The fourth electrode is located on the second epitaxial structure and electrically connected to the fourth semiconductor layer. The insulating layer covers the first epitaxial structure and the second epitaxial structure and has a first opening, a second opening, a third opening, and a fourth opening. The first pad is located on the insulating layer and electrically connected to the first electrode and the fourth electrode respectively through the first opening and the fourth opening. The second pad is located on the insulating layer and electrically connected to the second electrode through the second opening. The conductive structure is connected to the second pad and electrically connected to the third semiconductor layer through the third opening. A contact resistance formed between the conductive structure and the third semiconductor layer is greater than a contact resistance formed between the first electrode and the first semiconductor layer.

The disclosure further provides a light emitting diode structure including a light emitting diode, a protection diode, an insulating layer, a first pad, a second pad, and a conductive structure.

The light emitting diode includes a first epitaxial structure, a first electrode, and a second electrode. The first epitaxial structure includes a first semiconductor layer, a first light emitting layer, and a second semiconductor layer stacked in sequence. The first electrode is located on the first epitaxial structure and electrically connected to the first semiconductor layer, and the second electrode is located on the first epitaxial structure and electrically connected to the second semiconductor layer. The protection diode is connected in antiparallel to the light emitting diode and includes a second epitaxial structure and a fourth electrode. The second epitaxial structure includes a third semiconductor layer, a second light emitting layer, and a fourth semiconductor layer stacked in sequence. The first epitaxial structure and the second epitaxial structure are separated from each other. The fourth electrode is located on the second epitaxial structure and electrically connected to the fourth semiconductor layer. The insulating layer covers the first epitaxial structure and the second epitaxial structure and has a first opening, a second opening, a third opening, and a fourth opening. The first pad is located on the insulating layer and electrically connected to the first electrode and the fourth electrode respectively through the first opening and the fourth opening. The second pad is located on the insulating layer and electrically connected to the second electrode through the second opening. The conductive structure is connected to the second pad and electrically connected to the third semiconductor layer through the third opening. A material of first electrode directly contacting the first semiconductor layer is different from a material of the conductive structure directly contacting the third semiconductor layer.

The disclosure further provides a light emitting device using the light emitting diode structure according to any one of the above.

One advantage of the disclosure is to provide a light emitting diode chip and a light emitting device thereof. Through the arrangement in which the protection diode and the light emitting diode are connected in antiparallel and the contact resistance formed between the conductive structure and the third semiconductor layer is relatively large, the anti-electro-static discharge (ESD) capability of the light emitting diode chip is improved, especially the negative anti-ESD capability of the light emitting diode chip is improved. The anti-ESD capability of the bare chip is directly improved, the failure of the light emitting diode chip due to static electricity before completion of the packaging is avoided, and the costs of packaging the Zener diode are saved.

Additional features and advantages of the disclosure will be set forth in the following specification, and in part will be apparent from the specification or can be learned by practice of the disclosure. The objects and other beneficial effects of the disclosure can be achieved and obtained through the structures specifically pointed out in the specification, claims, and the like.

### BRIEF DESCRIPTION OF THE DRAWINGS

To make the technical solutions provided in the embodiments of the disclosure or the related art more clearly illustrated, several accompanying drawings required by the embodiments or the related art for description are briefly introduced as follows. Obviously, the drawings in the following description are some embodiments of the disclosure, and for a person having ordinary skill in the art, other drawings can be obtained based on these drawings without inventive effort. In the following description, the positional relationship described in the accompanying drawings is based on the direction in which the components are drawn in the drawings, unless otherwise specified.

FIG. 1 is a schematic structural top view of a light emitting diode structure according to a first embodiment of the disclosure.

FIG. 2 is a schematic longitudinal cross-sectional view taken along a line A-A of FIG. 1.

FIG. 3 is a schematic longitudinal cross-sectional view taken along a line B-B of FIG. 1.

FIG. 4 is a schematic structural top view of a light emitting diode structure according to a second embodiment of the disclosure.

FIG. 5 is a schematic longitudinal cross-sectional view taken along a line A-A of FIG. 4.

FIG. 6 is a schematic longitudinal cross-sectional view taken along a line B-B of FIG. 4.

FIG. 7 is a schematic structural top view of a light emitting diode structure according to a third embodiment of the disclosure.

FIG. 8 is a schematic longitudinal cross-sectional view taken along a line A-A of FIG. 7.

FIG. 9 is a schematic longitudinal cross-sectional view taken along a line B-B of FIG. 7.

FIG. 10 is a schematic structural top view of a light emitting diode structure according to a fourth embodiment of the disclosure.

FIG. 11 is a schematic dimensional view of FIG. 10.

FIG. 12 is a schematic longitudinal cross-sectional view taken along a line A-A of FIG. 10.

FIG. 13 is a schematic longitudinal cross-sectional view taken along a line B-B of FIG. 10.

FIG. 14 to FIG. 17 are schematic structural top views of the light emitting diode structure shown in FIG. 10 at various stages in a manufacturing process.

FIG. 18 is a schematic structural top view of a light emitting diode structure according to a fifth embodiment of the disclosure.

FIG. 19 is a schematic structural top view of a light emitting diode structure according to a sixth embodiment of the disclosure.

FIG. 20 is a schematic structural top view of a light emitting diode structure according to a seventh embodiment of the disclosure.

FIG. 21 is a schematic structural top view of a light emitting diode structure according to an eighth embodiment of the disclosure.

### DESCRIPTION OF THE EMBODIMENTS

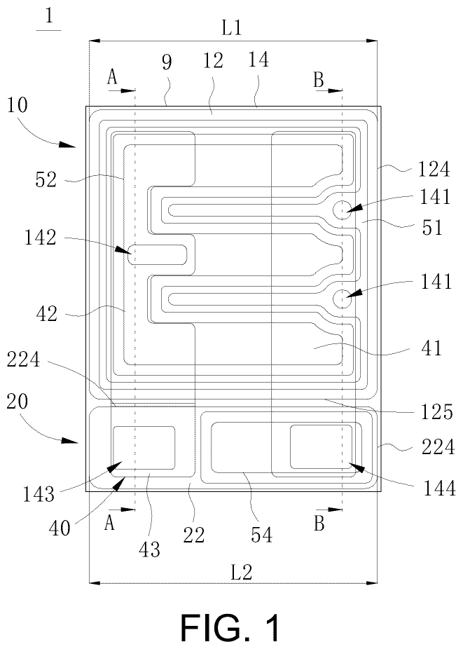

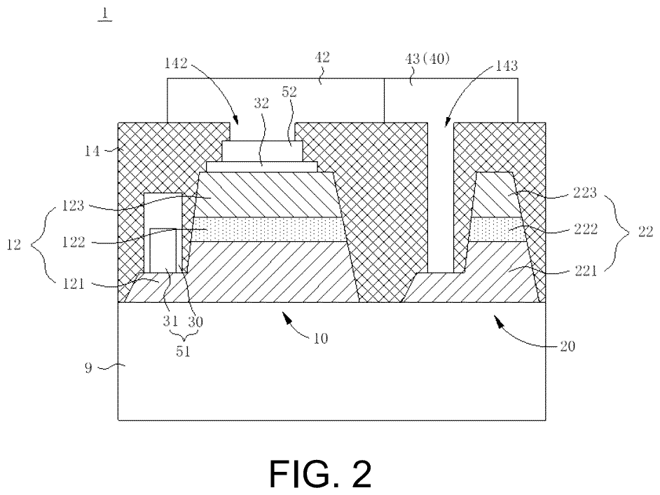

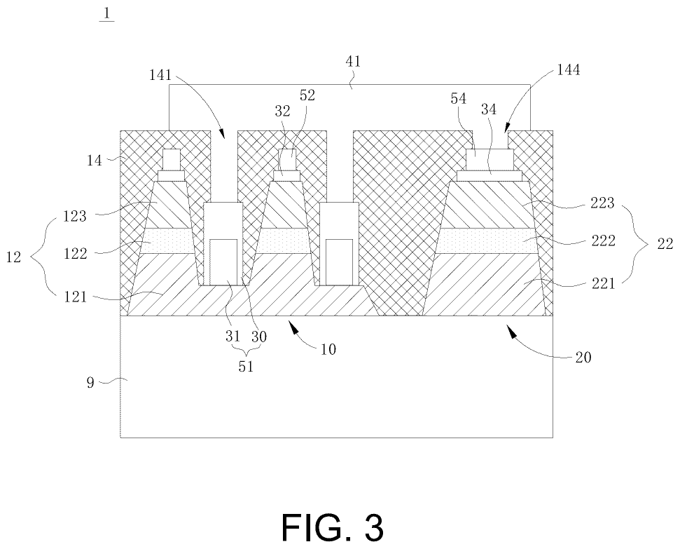

With reference to FIG. 1, FIG. 1 is a schematic structural top view of a light emitting diode structure 1 according to a first embodiment of the disclosure, FIG. 2 is a schematic longitudinal cross-sectional view taken along a line A-A of FIG. 1, and FIG. 3 is a schematic longitudinal cross-sectional view taken along a line B-B of FIG. 1. In order to achieve at least one of the advantages or other advantages, the first embodiment of the disclosure provides the light emitting diode structure 1. As shown in the figures, the light emitting diode structure 1 includes a light emitting diode 10, a protection diode 20, an insulating layer 14, a first pad 41, a second pad 42, and a conductive structure 40.

The light emitting diode 10 and the protection diode 20 are disposed on a substrate 9. The substrate 9 may be a transparent substrate, a non-transparent substrate, or a translucent substrate. The transparent substrate or the translucent substrate may allow light radiated by a light emitting layer to pass through the substrate 9 and reach a side of the substrate 9 away from an epitaxial structure. For instance, the substrate 9 may be any one of a sapphire flat substrate, a sapphire patterned substrate, a silicon substrate, a silicon carbide substrate, a gallium nitride substrate, and a glass substrate.

In some embodiments, a combined patterned substrate 9 may be used, and a pattern of the substrate 9 is a series of protruding structures. The protruding structure may be a one-layer or multi-layer structure, including at least one light extraction layer with a refractive index lower than that of the substrate 9. A thickness of the light extraction layer is greater than half a height of the protruding structure, which is more beneficial to the light output efficiency of the light emitting diode 10. Preferably, the protruding structure is in the form of a cannonball, and a material of the light extraction layer may have a refractive index of preferably less than 1.6, such as SiO₂. In some embodiments, the substrate 9 may be thinned or removed to form a thin film type chip.

The light emitting diode 10 includes a first epitaxial structure 12, a first electrode 51, and a second electrode 52. The first epitaxial structure 12 includes a first semiconductor layer 121, a first light emitting layer 122, and a second semiconductor layer 123 stacked in sequence from bottom to top. The first electrode 51 is located on the first epitaxial structure 12 and electrically connected to the first semiconductor layer 121. The second electrode 52 is located on the first epitaxial structure 12 and electrically connected to the second semiconductor layer 123. The first electrode 51 is generally made by first evaporating metal and then fusing the metal material at high temperature. For instance, a Ti/Al metal material is used, the Ti/Al metal material is first evaporated on the first semiconductor layer 121, and then the first electrode 51 is formed by high-temperature fusion. Therefore, a resistance of the first electrode 51 is often relatively small, which means that a contact resistance formed between the first electrode 51 and the first semiconductor layer 121 is relatively small. A material of the first electrode 51 may be selected from one or more of Cr, Pt, Au, Ni, Ti, Al, and PtAu.

The protection diode 20 is connected in antiparallel to the light emitting diode 10, so that the protection diode 20 may provide an electrical protection effect in the light emitting diode structure 1. The light emitting diode 10 is protected from being damaged, so a light emitting diode 10 chip having strong electro-static discharge (ESD) resistance is thus provided. The protection diode 20 includes a second epitaxial structure 22 and a fourth electrode 54. The second epitaxial structure 22 includes a third semiconductor layer 221, a second light emitting layer 222, and a fourth semiconductor layer 223 stacked in sequence from bottom to top. The first epitaxial structure 12 and the second epitaxial structure 22 are arranged to be separated from each other. The fourth electrode 54 is located on the second epitaxial structure 22 and electrically connected to the fourth semiconductor layer 223.

The antiparallel connection means connecting the anode of the light emitting diode 10 to the cathode of the protection diode 20, and the cathode of the light emitting diode 10 to the anode of the protection diode 20.

The light emitting diode 10 and the protection diode 20 are stacked regions electrically isolated from each other and may be composed of a nitride semiconductor layer. With this structure, the light emitting diode 10 may be configured to have a same height as the protection diode 20 on the same substrate. The light emitting diode 10 and the protection diode 10 may be formed by patterning a nitride semiconductor layer grown with a same growth procedure (e.g., metal-organic chemical vapor deposition (MOCVD), molecular beam epitaxy (MBE), etc.), so as to be separated from each other. Therefore, the process of forming the first semiconductor layer 121, the first light emitting layer 122, and the second semiconductor layer 123 may be the same as the process of forming the third semiconductor layer 221, the second light emitting layer 222, and the fourth semiconductor layer 223. Therefore, compositions and impurity densities of the first semiconductor layer 121, the first light emitting layer 122, and the second semiconductor layer 123 may be the same as compositions and impurity densities of the third semiconductor layer 221, the second light emitting layer 222, and the fourth semiconductor layer 223, respectively.

The first semiconductor layer 121 and the third semiconductor layer 221 are formed on the substrate 9. The two semiconductor layers grown on the substrate 9 may be gallium nitride semiconductor layers doped with n-type impurities, such as Si. In some embodiments, a buffer layer may be further provided between the first semiconductor layer 121 and the substrate 9. In some other embodiments, the first epitaxial structure 12 and the second epitaxial structure 22 may also be connected to the substrate 9 through an adhesive layer.

The first light emitting layer 122 and the second light emitting layer 222 may be a quantum well (QW) structure. In other embodiments, the first light emitting layer 122 and the second light emitting layer 222 may also be a multiple quantum well (MQW) structure, where the multiple quantum well structure includes a plurality of quantum well layers and a plurality of quantum barrier layers that are arranged in an alternating and repetitive manner. In addition, compositions and thicknesses of the well layers in the first light emitting layer 122 and the second light emitting layer 222 determine a wavelength of the generated light. In particular, by adjusting the compositions of the well layers, a light emitting layer that generates light of different colors such as ultraviolet, blue light, green light, etc. may be provided.

The second semiconductor layer 123 and the fourth semiconductor layer 223 may be gallium nitride-based semiconductor layers doped with p-type impurities, such as Mg. The first semiconductor layer 121, the second semiconductor layer 123, the third semiconductor layer 221, and the fourth semiconductor layer 223 may each have a single-layer structure, but the disclosure is not limited thereto. The semiconductor layers may be multiple layers or may include superlattice layers. Further, when the first semiconductor layer 121 and the third semiconductor layer 221 are doped with p-type impurities, the second semiconductor layer 123 and the fourth semiconductor layer 223 may be doped with n-type impurities.

The insulating layer 14 covers the first epitaxial structure 12 and the second epitaxial structure 22 and has a first opening 141, a second opening 142, a third opening 143, and a fourth opening 144. The first opening 141, the second opening 142, the third opening 143, and the fourth opening 144 are respectively located above the first semiconductor layer 121, the second semiconductor layer 123, the third semiconductor layer 221, and the fourth semiconductor layer 223. In an embodiment, a material of the insulating layer 14 includes a non-conductive material. The non-conductive material is preferably an inorganic material or a dielectric material. The inorganic material includes silicone or glass. The dielectric material includes aluminum oxide (AlO), silicon nitride (SiNx), silicon oxide (SiOx), titanium oxide (TiOx), or magnesium fluoride (MgFx). The material of the insulating layer 14 may be an electrically insulating material. For instance, the material of the insulating layer 14 may be silicon dioxide, silicon nitride, titanium oxide, tantalum oxide, niobium oxide, barium titanate, or a combination thereof, and the combination thereof may be, for example, a Bragg reflector (DBR) formed by repeated stacking of two materials.

Both the first pad 41 and the second pad 42 are located on the insulating layer 14. The first pad 41 is electrically connected to the first electrode 51 and the fourth electrode 54 respectively through the first opening 141 and the fourth opening 144. The second pad 42 is electrically connected to the second electrode 52 through the second opening 142. The first pad 41 and the second pad 42 may be formed together using a same material in a same process, and thus may have a same layer structure.

The conductive structure 40 is connected to the second pad 42 and electrically connected to the third semiconductor layer 221 through the third opening 143. Herein, a material of the conductive structure 40 and a material of the first electrode 51 are different, so that a contact resistance formed between the conductive structure 40 and the third semiconductor layer 221 is greater than a contact resistance formed between the first electrode 51 and the first semiconductor layer 121. In this way, the light emitting diode 10 is prevented from being damaged by ESD, and the anti-ESD capability of the light emitting diode structure 1 is improved, especially the negative anti-ESD capability. Three implementations of the conductive structure 40 are listed in the following paragraphs to facilitate understanding of the characteristics and structure of the conductive structure 40. It should be noted that the three implementations of the conductive structure 40 are only for understanding, but not for limiting the disclosure.

In an embodiment, as shown in FIG. 1 to FIG. 3, the conductive structure 40 may be a third pad 43. The third pad 43 is connected to the second pad 42 and electrically connected to the third semiconductor layer 221 through the third opening 143. A material of the third pad 43 is different from the material of the first electrode 51, so that a contact resistance formed between the third pad 43 and the third semiconductor layer 221 is greater than the contact resistance formed between the first electrode 51 and the first semiconductor layer 121. In this way, the light emitting diode 10 is protected, and the anti-ESD capability of the light emitting diode structure 1 is improved, especially the negative anti-ESD capability. As an alternative implementation, only the material of the third pad 43 directly contacting the third semiconductor layer 221 is different from the material of the first electrode 51 directly contacting the first semiconductor layer 121, so that the contact resistance formed between the third pad 43 and the third semiconductor layer 221 is greater than the contact resistance formed between the first electrode 51 and the first semiconductor layer 121.

The material of the first electrode 51 may be selected from one or more of Cr, Pt, Au, Ni, Ti, Al, and PtAu, and the material of the third pad 43 may be selected from one or more of Cr, Pt, Au, Ni, Ti, Al, and AuSn.

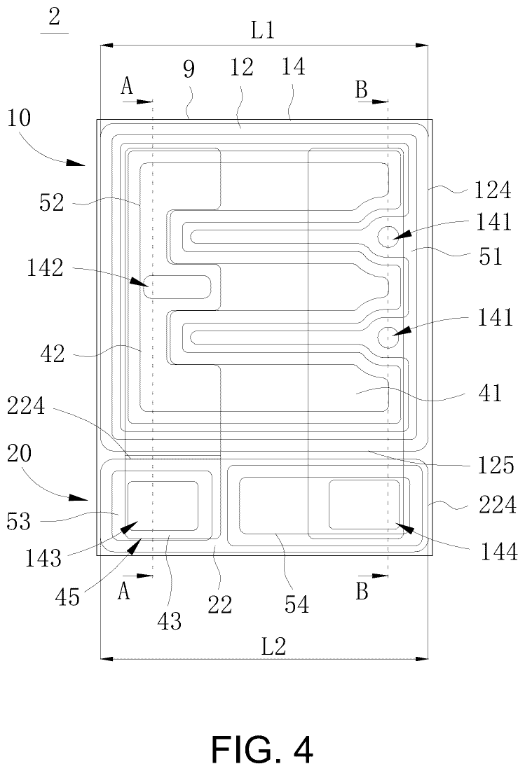

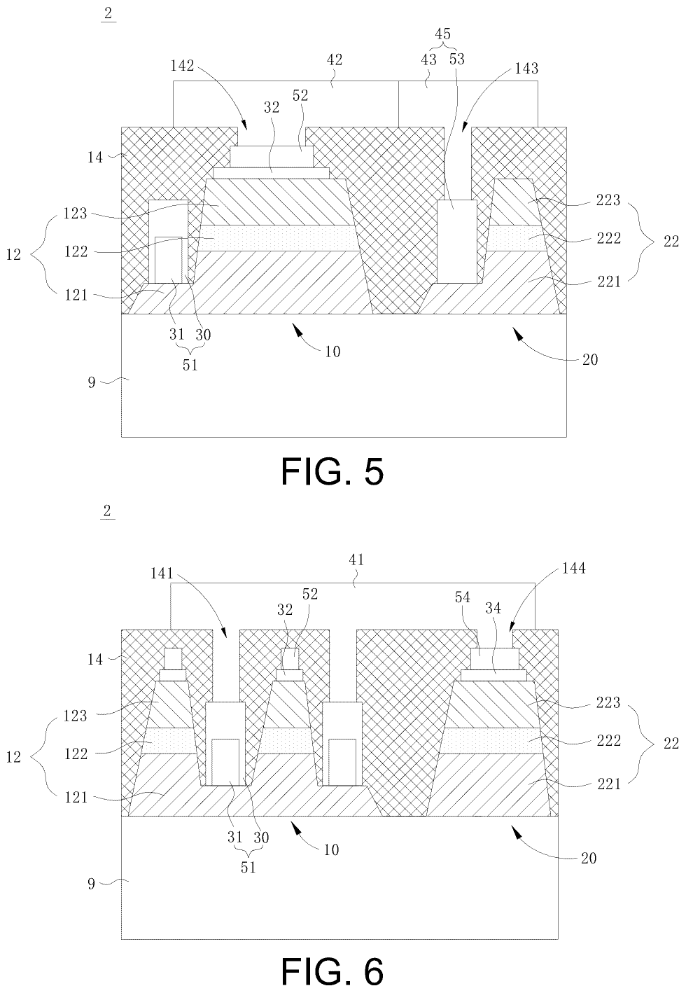

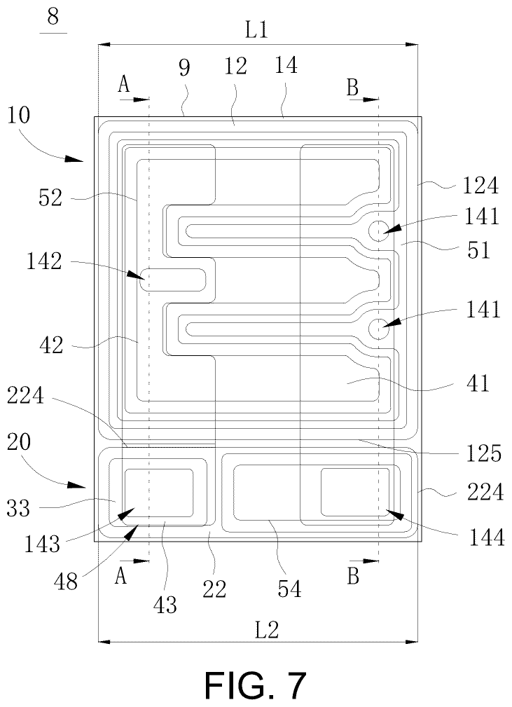

In an embodiment, as shown in FIG. 4 to FIG. 6, the conductive structure 45 may include a third electrode 53 and the third pad 43. The third electrode 53 is located on the second epitaxial structure 22 and electrically connected to the third semiconductor layer 221. The third pad 43 is connected to the second pad 42 and electrically connected to the third electrode 53 through the third opening 143. A material of the third electrode 53 is different from the material of the first electrode 51, so that a contact resistance formed between the third electrode 53 and the third semiconductor layer 221 is greater than the contact resistance formed between the first electrode 51 and the first semiconductor layer 121. In this way, the light emitting diode 10 is protected, and the anti-ESD capability of a light emitting diode structure 2 is improved, especially the negative anti-ESD capability. As an alternative implementation, only the material of the third electrode 53 directly contacting the third semiconductor layer 221 is different from the material of the first electrode 51 directly contacting the first semiconductor layer 121, so that the contact resistance formed between the third electrode 53 and the third semiconductor layer 221 is greater than the contact resistance formed between the first electrode 51 and the first semiconductor layer 121.

The material of the first electrode 51 may be selected from one or more of Cr, Pt, Au, Ni, Ti, Al, and PtAu, and the material of the third electrode 53 may be selected from one or more of Cr, Pt, Au, Ni, Ti, Al, and PtAu.

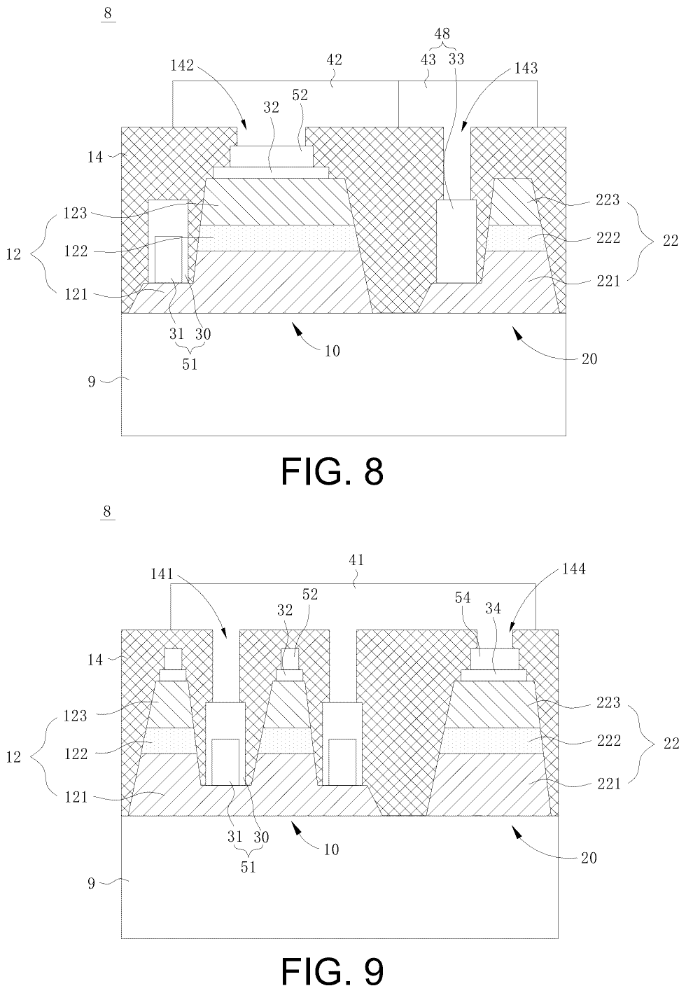

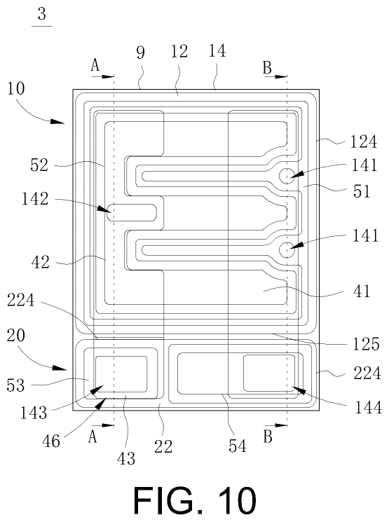

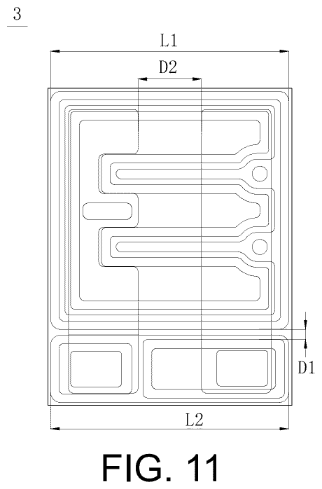

In an embodiment, as shown in FIG. 7 to FIG. 9, the conductive structure 48 may include a second transparent conductive layer 33 and the third pad 43. The second transparent conductive layer 33 is located on the second epitaxial structure 22 and electrically connected to the third semiconductor layer 221. The third pad 43 is connected to the second pad 42 and electrically connected to the second transparent conductive layer 33 through the third opening 143. A material of the second transparent conductive layer 33 is different from the material of the first electrode 51, so that a contact resistance formed between the second transparent conductive layer 33 and the third semiconductor layer 221 is greater than the contact resistance formed between the first electrode 51 and the first semiconductor layer 121. In this way, the light emitting diode 10 is protected, and the anti-ESD capability of a light emitting diode structure 8 is improved, especially the negative anti-ESD capability. As an alternative implementation, only the material of the second transparent conductive layer 33 directly contacting the third semiconductor layer 221 is different from the material of the first electrode 51 directly contacting the first semiconductor layer 121, so that the contact resistance formed between the second transparent conductive layer 33 and the third semiconductor layer 221 is greater than the contact resistance formed between the first electrode 51 and the first semiconductor layer 121.

The material of the first electrode 51 may be selected from one or more of Cr, Pt, Au, Ni, Ti, Al, and PtAu. The second transparent conductive layer 33 may be made of a transparent conductive material, such as indium-tin oxide, zinc-indium oxide, etc.

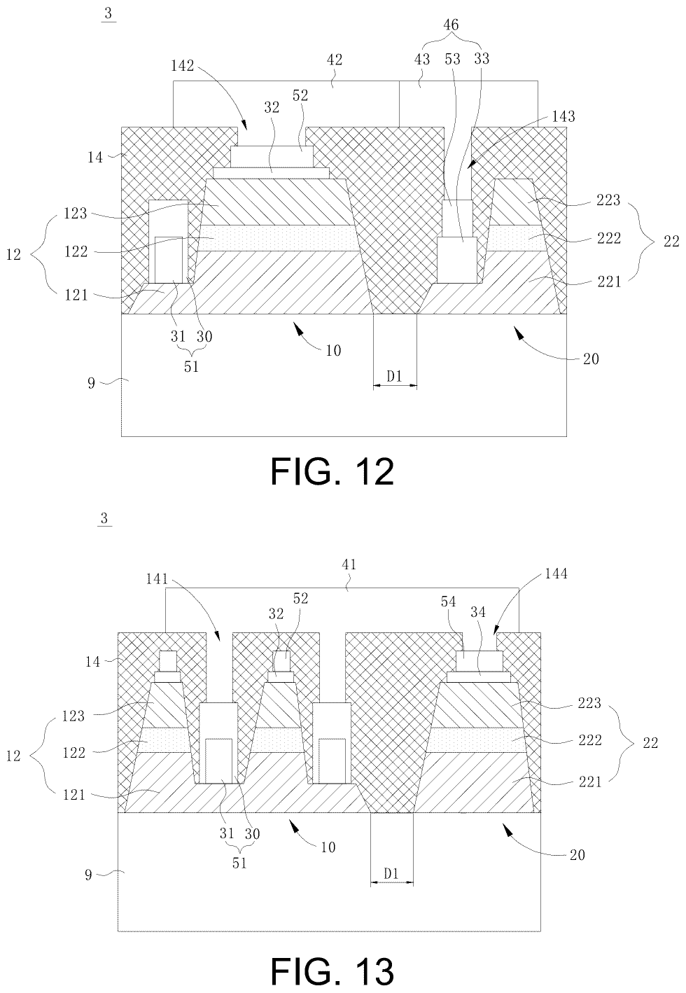

In an embodiment, as shown in FIG. 10 to FIG. 13, the conductive structure 46 may include the second transparent conductive layer 33, the third electrode 53, and the third pad 43. The second transparent conductive layer 33 is located on the second epitaxial structure 22 and electrically connected to the third semiconductor layer 221. The second transparent conductive layer 33 is located between the third electrode 53 and the third semiconductor layer 221. Preferably, a width of the second transparent conductive layer 33 is greater than a width of the third electrode 53. The third electrode 53 is connected to the second transparent conductive layer 33 and does not contact the third semiconductor layer 221. The third pad 43 is connected to the second pad 42 and electrically connected to the third electrode 53 through the third opening 143. Further, the material of the second transparent conductive layer 33 is different from the material of the first electrode 51, so that the contact resistance formed between the second transparent conductive layer 33 and the third semiconductor layer 221 is greater than the contact resistance formed between the first electrode 51 and the first semiconductor layer 121. In this way, the light emitting diode 10 is protected, and the anti-ESD capability of a light emitting diode structure 3 is improved, especially the negative anti-ESD capability. As an alternative implementation, only the material of the second transparent conductive layer 33 directly contacting the third semiconductor layer 221 is different from the material of the first electrode 51 directly contacting the first semiconductor layer 121, so that the contact resistance formed between the second transparent conductive layer 33 and the third semiconductor layer 221 is greater than the contact resistance formed between the first electrode 51 and the first semiconductor layer 121.

Overall, in the disclosure, the materials of the conductive structures 40, 45, and 46 are different from the material of the first electrode 51, so that the contact resistance formed between the conductive structures 40, 45, and 46 and the third semiconductor layer 221 is greater than the contact resistance formed between the first electrode 51 and the first semiconductor layer 121. When phenomena such as electro-static discharge occur and large energy passes through, the larger contact resistance formed between the conductive structures 40, 45, and 46 and the third semiconductor layer 221 provides strong isolation and buffering. The light emitting diode 10 is thereby protected, and the anti-ESD capability of the light emitting diode structure 2 is improved, especially the negative anti-ESD capability. That is, when an ESD surge voltage is generated, due to the larger contact resistance formed between the conductive structures 40, 45, and 46 and the third semiconductor layer 221, under the same voltage, the final impact current received is smaller, so it can withstand higher ESD impact under the same impact current. In addition, as an alternative in the disclosure, the material of the first electrode 51 directly contacting the first semiconductor layer 121 is different from the material of the conductive structures 40, 45, and 46 directly contacting the third semiconductor layer 221, so that the contact resistance formed between the conductive structures 40, 45, and 46 and the third semiconductor layer 221 is greater than the contact resistance formed between the first electrode 51 and the first semiconductor layer 121. In this way, the light emitting diode 10 is protected, and the anti-ESD capability of the light emitting diode structure 2 is improved, especially the negative anti-ESD capability.

The difference in materials not only refers to the different materials used to form the conductive structures 40, 45, and 46 and the first electrode 51, but also includes the possibility that the specific component contents are different when the conductive structures 40, 45, and 46 and the first electrode 51 are made of the same material. For instance, the first electrode 51 located on the first semiconductor layer 121 is made of the Ti/Al metal material. The Ti/Al metal material is first evaporated on the first semiconductor layer 121, and then high-temperature fusion is performed for manufacturing. The conductive structures 40, 45, and 46 located on the third semiconductor layer 221 are also made of the Ti/Al metal material but are not made through high-temperature fusion (but only by evaporation of metal). This implementation shall also fall within the scope of the disclosure in which the material of the conductive structures 40, 45, and 46 are different from the material of the first electrode 51.

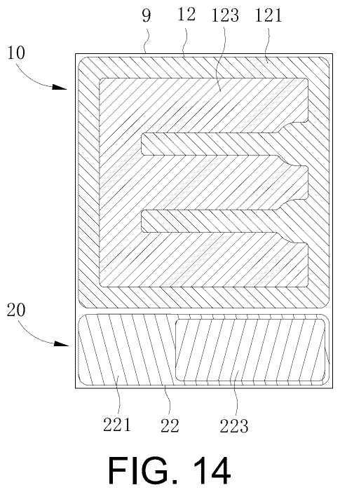

In an embodiment, as shown in FIG. 10 and FIG. 11, viewed from above the light emitting diode structure 3 toward the first epitaxial structure 12, the second epitaxial structure 22 is located outside the first epitaxial structure 12, and a length L2 of the second epitaxial structure 22 is greater than or equal to 50% of a width L1 of the first epitaxial structure 12 and less than or equal to 110% of the width L1 of the first epitaxial structure 12. Through the arrangement of these percentages, the effect of the protection diode 20 in providing improved electrical protection in the light emitting diode structure 3 is ensured. Without affecting the manufacturing process of the light emitting diode structure 3, a larger area of the protection diode 20 is formed, and the overall anti-ESD capability of the light emitting diode structure 3 may be better improved. If the protection diode 20 is smaller, the protection diode 20 cannot protect the light emitting diode 10. However, the disclosure is not limited thereto. In the light emitting diode structure 3, by arranging the first pad 41 and the second pad 42 on the light emitting diode 10 perpendicular to the protection diode 20, it can also be ensured that the protection diode 20 provides improved electrical protection effect in the light emitting diode structure 3.

Further, the light emitting diode 10 and the protection diode 20 may be in a square shape, and both the first epitaxial structure 12 and the second epitaxial structure 22 have four sides. Viewed from above the light emitting diode structure 3 toward the first epitaxial structure 12, the second epitaxial structure 22 is located outside one side 124 of the first epitaxial structure 12. Herein, this one side is defined as a critical edge 125. A length of a side 224 of the second epitaxial structure 22 adjacent to the critical edge 125 is greater than or equal to 50% of a length of the critical edge 125 of the first epitaxial structure 12 and less than or equal to 110% of the length of the critical edge 125 of the first epitaxial structure 12. To be specific, the second epitaxial structure 22 is located on the side of a straight line where the critical edge 125 is located away from the first epitaxial structure 12 and does not cross or touch the straight line where the critical edge 125 is located. In this way, the overall manufacturing process may be simplified, a larger area of the protection diode 20 is obtained, and the anti-ESD capability of the light emitting diode structure 3 may be improved.

In an embodiment, viewed from above the light emitting diode structure 3 toward the first epitaxial structure 12, as shown in FIG. 10 and FIG. 11, a proportion of a horizontal projected area of the second epitaxial structure 22 to a horizontal projected area of the first epitaxial structure 12 is greater than or equal to 10% and less than or equal to 35%. With this arrangement, a size of the light emitting diode structure 3 may be reduced as much as possible while ensuring that the light emitting diode structure 3 has improved anti-ESD capability. As an alternative implementation, viewed from above the light emitting diode structure 3 toward the first epitaxial structure 12, the horizontal projected area of the second epitaxial structure 22 may account for greater than or equal to 5% and less than or equal to 50% of the horizontal projected area of the light emitting diode structure 3.

The horizontal projected area refers to a projected area of each element (e.g., the first epitaxial structure 12, the second epitaxial structure 12, etc.) projected onto a horizontal surface when the light emitting diode structure 3 is placed directly on the horizontal surface, and herein, the direction from the first epitaxial structure 12 to the first pad 41 is a vertical direction perpendicular to the horizontal surface and the direction from the second epitaxial structure 22 to the first pad 41 is also a vertical direction perpendicular to the horizontal surface.

In an embodiment, viewed from above the light emitting diode structure 3 toward the first epitaxial structure 12, as shown in FIG. 10 and FIG. 11, a first minimum distance D1 is provided between the first epitaxial structure 12 and the second epitaxial structure 22, and the first minimum distance D1 is less than 30 μm and greater than 0 μm. In this way, the light emitting diode structure 3 is ensured to have improved anti-ESD capability, and the size of the light emitting diode structure 3 may also be reduced as much as possible.

In an embodiment, viewed from above the light emitting diode structure 3 toward the first epitaxial structure 12, as shown in FIG. 10 and FIG. 11, a second minimum distance D2 is provided between the first pad 41 and the second pad 42, and the second minimum distance D2 may be between 30 μm and 230 μm. A reasonable spacing may be designed based on a package size of a preset terminal.

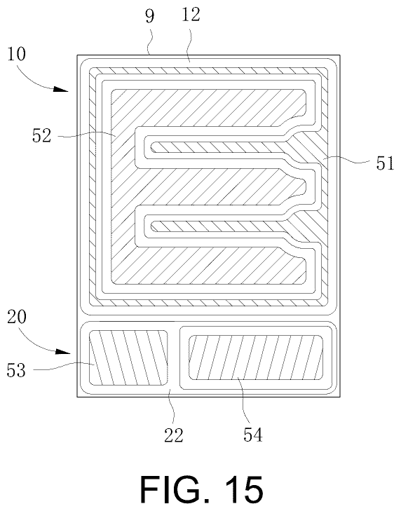

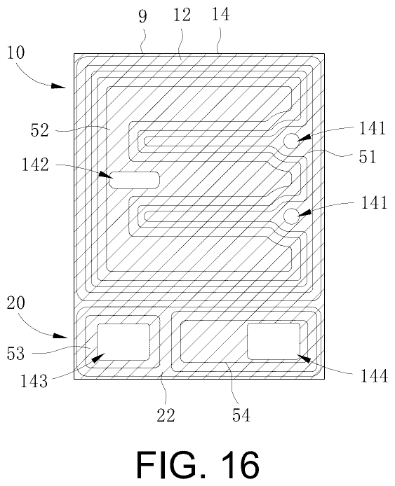

In an embodiment, as shown in FIG. 12 and FIG. 13, the light emitting diode 10 further includes a first transparent conductive layer 32 located between the second electrode 52 and the second semiconductor layer 123. The first electrode 51 includes a connecting electrode 30 and an ohmic contact electrode 31 connected to the first semiconductor layer 121, and the connecting electrode 30 is connected to the ohmic contact electrode 31. The first pad 41 is connected to the connecting electrode 30 through the first opening 141. The protection diode 20 further includes a third transparent conductive layer 34 located between the fourth electrode 54 and the fourth semiconductor layer 223.

Each transparent conductive layer (e.g., the first transparent conductive layer 32, the second transparent conductive layer 33, and the third transparent conductive layer 34) is made of a transparent conductive material. The lateral current expansion effect may be ensured, and the reliability of the light emitting diode structure 3 may be improved in this way. As an example, the transparent conductive material may include indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium doped zinc oxide (GZO), tungsten doped indium oxide (IWO), or zinc oxide (ZnO), but the embodiments of the disclosure are not limited thereto. A thickness of the second transparent conductive layer 33 may be between 0.005 μm and 0.5 μm.

The ohmic contact electrode 31 may form a good ohmic contact with the first semiconductor layer 121, which is beneficial to the input and output of current. The connecting electrode 30 may protect the ohmic contact electrode 31 and provide support, cushioning and other functions. Preferably, the connecting electrode 30 may cover the ohmic contact electrode 31 to further prevent metal precipitation, such as Al precipitation, in the ohmic contact electrode 31. A material of the connecting electrode 30 may be selected from one or more of Cr, Pt, Au, Ni, Ti, and Al, and a material of the ohmic contact electrode 31 may be selected from one or more of Ti, Al, Au, and Pt.

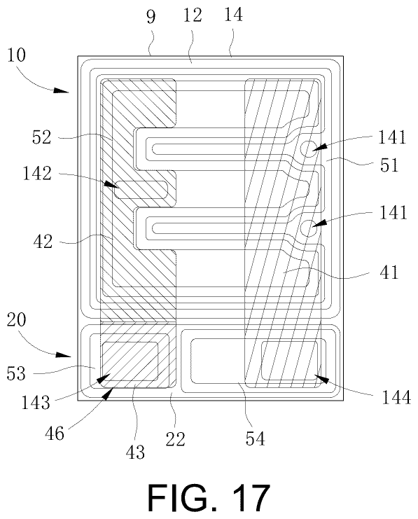

With reference to FIG. 14 to FIG. 17, FIG. 14 to FIG. 17 are schematic structural top views of the light emitting diode structure shown in FIG. 10 at various stages in a manufacturing process. It should be noted that, in order to facilitate understanding of the positions, shapes, and relative relationships the layers in the top views, the light emitting diode structure 3 shown in FIG. 10 is taken as an example, and the manufacturing process of each stage in FIG. 10 is described with reference to FIG. 14 to FIG. 17. In contrast, the stacking arrangement of the layers in the top views corresponding to other embodiments may also be understood adaptively with reference to FIG. 14 to FIG. 17. Since the ohmic contact electrode 31, the first transparent conductive layer 32, the second transparent conductive layer 33, the third transparent conductive layer 34, and other structures are omitted in FIG. 10, the process stages are also omitted accordingly. The hatched portions in each figure in FIG. 14 to FIG. 17 represent additional structures in the process corresponding to the current figure compared to the process corresponding to the previous figure.

First, with reference to FIG. 14, the first epitaxial structure 12 of the light emitting diode 10 and the second epitaxial structure 22 of the protection diode 20 are grown on the substrate 9. The first epitaxial structure 12 is spaced apart from the second epitaxial structure 22 by a certain distance. The first epitaxial structure 12 includes the first semiconductor layer 121, the first light emitting layer 122, and the second semiconductor layer 123 stacked in sequence from bottom to top. The second epitaxial structure 22 includes the third semiconductor layer 221, the second light emitting layer 222, and the fourth semiconductor layer 223 stacked in sequence from bottom to top. Next, the first semiconductor layer 121 and the third semiconductor layer 221 are etched from the second semiconductor layer 123 and the fourth semiconductor layer 223 respectively to form through holes to expose the first semiconductor layer 121 and the third semiconductor layer 221. In addition, edge portions of the first epitaxial structure 12 and the second epitaxial structure 22 may be selectively removed to further expose the substrate 9 to facilitate subsequent cutting and other processes.

Next, with reference to FIG. 15, the first electrode 51 and the second electrode 52 electrically connected to the first semiconductor layer 121 and the second semiconductor layer 123 respectively are formed on the first epitaxial structure 12. The third electrode 53 and the fourth electrode 54 electrically connected to the third semiconductor layer 221 and the fourth semiconductor layer 223 respectively are formed on the second epitaxial structure 22.

Next, with reference to FIG. 16, the insulating layer 14 is formed on the first epitaxial structure 12 and the second epitaxial structure 22. The insulating layer 14 covers the substrate 9, the first epitaxial structure 12, the second epitaxial structure 22, the first electrode 51, the second electrode 52, the third electrode 53, and the fourth electrode 54. The insulating layer 14 has the first opening 141, the second opening 142, the third opening 143, and the fourth opening 144. The first opening 141, the second opening 142, the third opening 143, and the fourth opening 144 are respectively located above the first electrode 51, the second electrode 52, the third electrode 53, and the fourth electrode 54 for exposing the electrodes.

Finally, with reference to FIG. 17, the first pad 41, the second pad 42, and the third pad 43 are formed on the insulating layer 14. The first pad 41 is electrically connected to the first electrode 51 and the fourth electrode 54 respectively through the first opening 141 and the fourth opening 144. The second pad 42 is electrically connected to the second electrode 52 through the second opening 142. The third pad 43 is connected to the second pad 42 and electrically connected to the third semiconductor layer 221 through the third opening 143.

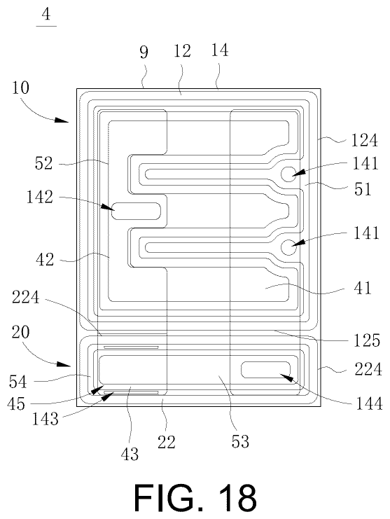

With reference to FIG. 18, FIG. 18 is a schematic structural top view of a light emitting diode structure 4 according to a fifth embodiment of the disclosure. Compared to the light emitting diode structure 2 shown in the second embodiment of FIG. 4, in the light emitting diode structure 4 of this embodiment, viewed from above the light emitting diode structure 4 toward the first epitaxial structure 12, the third electrode 53 has a ring shape, and the fourth electrode 54 has a block shape. The corresponding third opening 143 and the fourth opening 144 are also adaptively adjusted to ensure a smooth circuit. Herein, the block-shaped fourth electrode 54 is located inside the ring-shaped third electrode 53, which can make the light emitting diode structure 4 exhibit an improved anti-ESD effect.

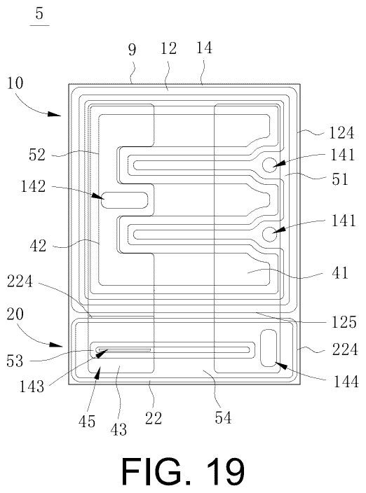

With reference to FIG. 19, FIG. 19 is a schematic structural top view of a light emitting diode structure 5 according to a sixth embodiment of the disclosure. Compared to the light emitting diode structure 2 shown in the second embodiment of FIG. 4, in the light emitting diode structure 5 of this embodiment, viewed from above the light emitting diode structure 5 toward the first epitaxial structure 12, the third electrode 53 has a block shape, and the fourth electrode 54 has a ring shape. The corresponding third opening 143 and the fourth opening 144 are also adaptively adjusted to ensure a smooth circuit. Herein, the block-shaped third electrode 53 is located inside the ring-shaped fourth electrode 54, which can make the light emitting diode structure 5 exhibit an improved anti-ESD effect.

The shape of the electrodes in the abovementioned FIG. 18 and FIG. 19 is a closed-ring shape, but the disclosure is not limited to this, and one of the third electrode 53 and the fourth electrode 54 has a non-closed-ring shape. That is, in the case of an open-ring shape, the other electrode is in the shape of a block, and the open-ring-shaped electrode sandwiching the block-shaped electrode may also improve the anti-ESD capability of the light emitting diode structure. For instance, the open-ring shape may be a “U” shape, a “=” shape, etc., and the block shape may be a square, a round block, etc. The sandwiching may understood as meaning that the block is located within the “U-shaped notch, or that the block is located within the two parallel sides of the “=” shape. Generally, one of the third electrode 53 and the fourth electrode 54 is located on the outside, and the other electrode is located on the opposite inside, so that the anti-ESD capability of the light emitting diode structure may be improved.

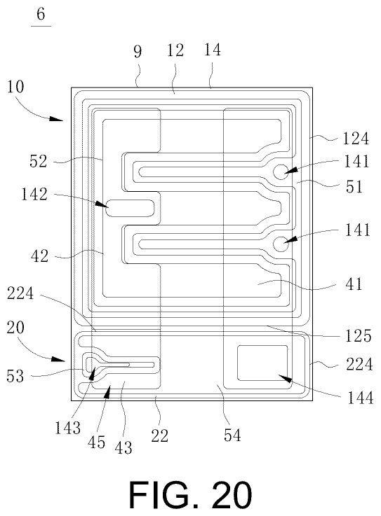

With reference to FIG. 20, FIG. 20 is a schematic structural top view of a light emitting diode structure 6 according to a seventh embodiment of the disclosure. Compared to the light emitting diode structure 2 shown in the second embodiment of FIG. 4, in the light emitting diode structure 6 of this embodiment, viewed from above the light emitting diode structure 6 toward the first epitaxial structure 12, a horizontal projected area of the fourth electrode 54 is greater than a horizontal projected area of the third electrode 53. The negative anti-ESD capability of the light emitting diode 10 may be effectively improved, that is, the anti-ESD capability of the first semiconductor side of the light emitting diode 10.

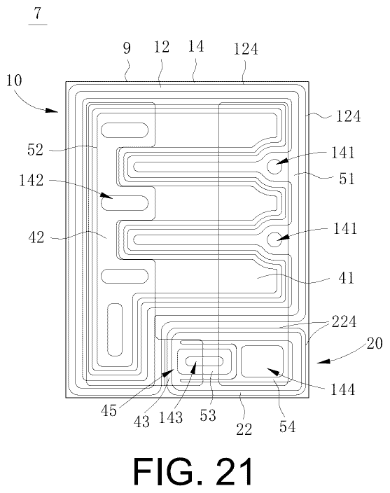

With reference to FIG. 21, FIG. 21 is a schematic structural top view of a light emitting diode structure 7 according to an eighth embodiment of the disclosure. Compared to the light emitting diode structure 2 shown in the second embodiment of FIG. 4, in the light emitting diode structure 7 of this embodiment, viewed from above the light emitting diode structure 7 toward the first epitaxial structure 12, the protection diode 20 is disposed at the corner of the light emitting diode structure 7 instead of being disposed parallel to the light emitting diode 10. The length L2 of the second epitaxial structure 22 of the protection diode 20 is still greater than or equal to 50% of the width L1 (i.e., the length value of the upper side 124 of the first epitaxial structure 12 in FIG. 21) of the first epitaxial structure 12 and less than or equal to 110% of the width L1 of the first epitaxial structure 12, so that the protection diode 20 has a larger area. With this arrangement, the manufacturing process of the light emitting diode structure 7 is simplified, and the anti-ESD capability of the light emitting diode structure 7 may be improved.

It should be noted that the aforementioned light emitting diode structures 1, 2, 3, 4, 5, 6, 7, and 8 are mainly used for ultraviolet rays (UV) products, and their wavelength range may be between 220 nm and 420 nm.

This embodiment provides a light emitting device that adopts the light emitting diode structures 1, 2, 3, 4, 5, 6, 7, and 8 provided in any of the above embodiments. Description of the specific structure and technical effects is not repeated herein. The lighting device may be a lighting device for UV products or UVC products.

In view of the foregoing, in the light emitting diode structure 1 and the light emitting device provided by the disclosure, by designing the protection diode 20 and optimizing the design and structural matching of the protection diode 20, the negative anti-ESD capability is improved, and the anti-ESD capability of the light emitting diode structure 1 is significantly improved. Further, the possibility of chiplet damage due to ESD after spot testing is reduced, and the abnormality rate of finished products is lowered. In the light emitting diode structure 1, through the arrangement in which the protection diode 20 and the light emitting diode 10 are connected in antiparallel and the contact resistance formed between the conductive structures 40, 45, 46 and the third semiconductor layer 221 is relatively large, the anti-ESD capability of the light emitting diode 10 chip is improved, especially the negative anti-ESD capability of the light emitting diode 10 chip is improved. The anti-ESD capability of the bare chip is directly improved, the failure of the light emitting diode 10 chip due to static electricity before completion of the packaging is avoided, and the costs of packaging the Zener diode are saved.

What is claimed is:

1. A light emitting diode structure, comprising:
a light emitting diode comprising a first epitaxial structure, a first electrode, and a second electrode, wherein the first epitaxial structure comprises a first semiconductor layer, a first light emitting layer, and a second semiconductor layer stacked in sequence, the first electrode is located on the first epitaxial structure and electrically connected to the first semiconductor layer, and the second electrode is located on the first epitaxial structure and electrically connected to the second semiconductor layer;
a protection diode connected in antiparallel to the light emitting diode, wherein the protection diode comprises a second epitaxial structure and a fourth electrode, the second epitaxial structure comprises a third semiconductor layer, a second light emitting layer, and a fourth semiconductor layer stacked in sequence, the first epitaxial structure and the second epitaxial structure are separated from each other, and the fourth electrode is located on the second epitaxial structure and electrically connected to the fourth semiconductor layer;
an insulating layer covering the first epitaxial structure and the second epitaxial structure and having a first opening, a second opening, a third opening, and a fourth opening;
a first pad located on the insulating layer and electrically connected to the first electrode and the fourth electrode respectively through the first opening and the fourth opening;
a second pad located on the insulating layer and electrically connected to the second electrode through the second opening; and
a conductive structure connected to the second pad and electrically connected to the third semiconductor layer through the third opening,
wherein a material of the conductive structure and a material of the first electrode are different.

2. The light emitting diode structure according to claim 1, wherein the conductive structure comprises a third pad connected to the second pad and electrically connected to the third semiconductor layer through the third opening.

3. The light emitting diode structure according to claim 1, wherein the conductive structure comprises a second transparent conductive layer and a third pad, the second transparent conductive layer is located on the second epitaxial structure and electrically connected to the third semiconductor layer, and the third pad is connected to the second pad and electrically connected to the second transparent conductive layer through the third opening.

4. The light emitting diode structure according to claim 1, wherein the conductive structure comprises a third electrode and a third pad, the third electrode is located on the second epitaxial structure and electrically connected to the third semiconductor layer, and the third pad is connected to the second pad and electrically connected to the third electrode through the third opening.

5. The light emitting diode structure according to claim 1, wherein the conductive structure comprises a second transparent conductive layer, a third electrode, and a third pad, the second transparent conductive layer is located on the second epitaxial structure and electrically connected to the third semiconductor layer, the third electrode is located between the second transparent conductive layer and the third pad, and the third pad is connected to the second pad and electrically connected to the third electrode through the third opening.

6. The light emitting diode structure according to claim 5, wherein viewed from above the light emitting diode structure toward the first epitaxial structure, the third electrode is in a ring shape, the fourth electrode is in a block shape, and the fourth electrode is located inside the ring-shaped third electrode, or
the fourth electrode is in a ring shape, the third electrode is in a block shape, and the third electrode is located inside the ring-shaped fourth electrode.

7. The light emitting diode structure according to claim 5, wherein viewed from above the light emitting diode structure toward the first epitaxial structure, the third electrode is in an open ring shape, the fourth electrode is in a block shape, and the third electrode surrounds the fourth electrode, or
the third electrode is in a block shape, the fourth electrode is in an open ring shape, and the fourth electrode surrounds the third electrode.

8. The light emitting diode structure according to claim 5, wherein viewed from above the light emitting diode structure toward the first epitaxial structure, a horizontal projected area of the fourth electrode is greater than a horizontal projected area of the third electrode.

9. The light emitting diode structure according to claim 5, wherein a thickness of the second transparent conductive layer is between 5 nm and 500 nm.

10. The light emitting diode structure according to claim 1, wherein the light emitting diode further comprises a first transparent conductive layer located between the second electrode and the second semiconductor layer, the protection diode further comprises a third transparent conductive layer located between the fourth electrode and the fourth semiconductor layer.

11. The light emitting diode structure according to claim 1, wherein the first electrode comprises a connecting electrode and an ohmic contact electrode connected to the first epitaxial structure, the connecting electrode is connected to the ohmic contact electrode, and the first pad is connected to the connecting electrode through the first opening.

12. The light emitting diode structure according to claim 1, wherein viewed from above the light emitting diode structure toward the first epitaxial structure, the second epitaxial structure is located outside the first epitaxial structure, a length of the second epitaxial structure is greater than or equal to 50% of a width of the first epitaxial structure and less than or equal to 110% of the width of the first epitaxial structure.

13. The light emitting diode structure according to claim 1, wherein viewed from above the light emitting diode structure toward the first epitaxial structure, both the light emitting diode and the protection diode are in a square shape.

14. The light emitting diode structure according to claim 1, wherein a wavelength range of the light emitting diode structure is between 220 nm and 420 nm.

15. A light emitting diode structure, comprising:
a light emitting diode comprising a first epitaxial structure, a first electrode, and a second electrode, wherein the first epitaxial structure comprises a first semiconductor layer, a first light emitting layer, and a second semiconductor layer stacked in sequence, the first electrode is located on the first epitaxial structure and electrically connected to the first semiconductor layer, and the second electrode is located on the first epitaxial structure and electrically connected to the second semiconductor layer;
a protection diode connected in antiparallel to the light emitting diode, wherein the protection diode comprises a second epitaxial structure and a fourth electrode, the second epitaxial structure comprises a third semiconductor layer, a second light emitting layer, and a fourth semiconductor layer stacked in sequence, the first epitaxial structure and the second epitaxial structure are separated from each other, and the fourth electrode is located on the second epitaxial structure and electrically connected to the fourth semiconductor layer;
an insulating layer covering the first epitaxial structure and the second epitaxial structure and having a first opening, a second opening, a third opening, and a fourth opening;
a first pad located on the insulating layer and electrically connected to the first electrode and the fourth electrode respectively through the first opening and the fourth opening;
a second pad located on the insulating layer and electrically connected to the second electrode through the second opening; and
a conductive structure connected to the second pad and electrically connected to the third semiconductor layer through the third opening,
wherein a contact resistance formed between the conductive structure and the third semiconductor layer is greater than a contact resistance formed between the first electrode and the first semiconductor layer.

16. The light emitting diode structure according to claim 15, wherein the conductive structure comprises a third pad connected to the second pad and electrically connected to the third semiconductor layer through the third opening, and a contact resistance formed between the third pad and the third semiconductor layer is greater than the contact resistance formed between the first electrode and the first semiconductor layer.

17. The light emitting diode structure according to claim 15, wherein the conductive structure comprises a second transparent conductive layer and a third pad, the second transparent conductive layer is located on the second epitaxial structure and electrically connected to the third semiconductor layer, the third pad is connected to the second pad and electrically connected to the second transparent conductive layer through the third opening, a contact resistance formed between the second transparent conductive layer and the third semiconductor layer is greater than the contact resistance formed between the first electrode and the first semiconductor layer.

18. The light emitting diode structure according to claim 15, wherein the conductive structure comprises a third electrode and a third pad, the third electrode is located on the second epitaxial structure and electrically connected to the third semiconductor layer, and the third pad is connected to the second pad and electrically connected to the third electrode through the third opening, a contact resistance formed between the third electrode and the third semiconductor layer is greater than the contact resistance formed between the first electrode and the first semiconductor layer.

19. The light emitting diode structure according to claim 15, wherein the conductive structure comprises a second transparent conductive layer, a third electrode, and a third pad, the second transparent conductive layer is located on the second epitaxial structure and electrically connected to the third semiconductor layer, the third electrode is connected to the second transparent conductive layer, the third pad is connected to the second pad and electrically connected to the third electrode through the third opening, a contact resistance formed between the second transparent conductive layer and the third semiconductor layer is greater than the contact resistance formed between the first electrode and the first semiconductor layer.

20. A light emitting diode structure, comprising:
a light emitting diode comprising a first epitaxial structure, a first electrode, and a second electrode, wherein the first epitaxial structure comprises a first semiconductor layer, a first light emitting layer, and a second semiconductor layer stacked in sequence, the first electrode is located on the first epitaxial structure and electrically connected to the first semiconductor layer, and the second electrode is located on the first epitaxial structure and electrically connected to the second semiconductor layer;
a protection diode connected in antiparallel to the light emitting diode, wherein the protection diode comprises a second epitaxial structure and a fourth electrode, the second epitaxial structure comprises a third semiconductor layer, a second light emitting layer, and a fourth semiconductor layer stacked in sequence, the first epitaxial structure and the second epitaxial structure are separated from each other, and the fourth electrode is located on the second epitaxial structure and electrically connected to the fourth semiconductor layer;
an insulating layer covering the first epitaxial structure and the second epitaxial structure and having a first opening, a second opening, a third opening, and a fourth opening;
a first pad located on the insulating layer and electrically connected to the first electrode and the fourth electrode respectively through the first opening and the fourth opening;
a second pad located on the insulating layer and electrically connected to the second electrode through the second opening; and
a conductive structure connected to the second pad and electrically connected to the third semiconductor layer through the third opening,
wherein a material of the first electrode directly contacting the first semiconductor layer is different from a material of the conductive structure directly contacting the third semiconductor layer.

21. The light emitting diode structure according to claim 20, wherein the conductive structure comprises a third pad connected to the second pad and directly connected to the third semiconductor layer through the third opening, and a material of the third pad is different from the material of the first electrode.

22. The light emitting diode structure according to claim 20, wherein the conductive structure comprises a second transparent conductive layer and a third pad, the second transparent conductive layer is located on the second epitaxial structure and electrically connected to the third semiconductor layer, the third pad is connected to the second pad and electrically connected to the second transparent conductive layer through the third opening, a material of the second transparent conductive layer is different from the material of the first electrode.

23. The light emitting diode structure according to claim 20, wherein the conductive structure comprises a third electrode and a third pad, the third electrode is directly connected to the third semiconductor layer, the third pad is connected to the second pad and electrically connected to the third electrode through the third opening, and a material of the third electrode is different from the material of the first electrode.

24. The light emitting diode structure according to claim 20, wherein the conductive structure comprises a second transparent conductive layer, a third electrode, and a third pad, the second transparent conductive layer is directly connected to the third semiconductor layer, the third electrode is connected to the second transparent conductive layer, the third pad is connected to the second pad and electrically connected to the third electrode through the third opening, and a material of the second transparent conductive layer is different from the material of the first electrode.

25. A light emitting device using the light emitting diode structure according to claim 1.
